(19) United States
(12) Patent Application Publication
(10) Pub. No.: US 2010/0236480 A1
(43) Pub. Date: Sep. 23, 2010

(54) RAW MATERIAL GAS SUPPLY SYSTEM AND FILM FORMING APPARATUS

(75) Inventors: Masamichi Hara, Yamanashi-ken (JP); Atsushi Gomi, Yamanashi-ken (JP); Shinji Maekawa, Yamanashi-ken (JP); Kaoru Yamamoto, Yamanashi-ken (JP); Satoshi Taga, Yamanashi-ken (JP)

Correspondence Address: SMITH, GAMBRELL & RUSSELL, 1130 CONNECTICUT AVENUE, N.W., SUITE 1130, WASHINGTON, DC, 20036, US

(73) Assignee: TOKYO ELECTRON LIMITED, Tokyo-To (JP)

(21) Appl. No.: 12/680,041

(22) PCT Filed: Sep. 22, 2008
(86) PCT No.: PCT/JP2008/067118

§ 371 Date: Jun. 4, 2010

(30) Foreign Application Priority Data
Sep. 28, 2007 (JP) 2007-255059

(51) Int. Cl. C23C 16/54; F15D 1/00

(52) U.S. Cl. 118/725; 137/560; 137/551

(57) ABSTRACT

A raw material gas supply system (6) supplies a raw material gas to a gas use system (2) kept in a reduced pressure atmosphere. The system includes: a raw material tank (40) for storing a liquid raw material or a solid raw material; a raw material conduit (46) connected at one end to the raw material tank and connected at the other end to the gas use system; a carrier gas supply mechanism (54), connected to the raw material tank, for supplying a carrier gas into the raw material tank while controlling the flow rate of the gas; on-off valves (48, 50) interposed in the raw material conduit; a heater (64) for heating the raw material conduit and the on-off valves; and a temperature control device (92) for controlling the heater, wherein the raw material conduit and the on-off valves are each formed of a metal material having good thermal conductivity.

### TECHNICAL FIELD

The present invention relates to a film forming apparatus for forming a film on the surface of an object to be processed, such as a semiconductor wafer, and to a supply system for supplying a raw material gas to the film forming apparatus, and more particularly to a raw material gas supply system and a film forming apparatus for a semiconductor device, which are useful for gasifying and supplying a raw material which has a low vapor pressure and hardly evaporates.

### BACKGROUND ART

In the manufacturing of a semiconductor device, a semiconductor wafer is generally subjected to various processings, such as film forming and pattern etching, carried out repeatedly to produce a desired device. To meet the recent demand for more highly integrated and finer semiconductor devices, line widths and hole diameters are becoming increasingly smaller. Such size reduction necessitates lowering of electrical resistance for interconnect materials and filling materials. Therefore, copper and tungsten, which have a very low electrical resistance and are inexpensive, tend to be used (e.g. JP 2000-77365 A and JP 2000-178734 A). When copper is used as an interconnect material or a filling material, a tantalum (Ta) film, a tantalum nitride (TaN) film, or the like is generally used as an underlying barrier layer in consideration of adhesion with copper, the effect of preventing thermal diffusion of the metal, etc. When tungsten is used as an interconnect material or a filling material, a titanium (Ti) film, a titanium nitride (TiN) film, or the like is generally used as an underlying barrier layer in consideration of adhesion with tungsten, the effect of preventing thermal diffusion of the metal, etc.

The Ta film or Ti film, or a film containing such a metal can be formed, for example, in the following manner: First, a raw material tank, in which a solid raw material, for example, is stored, is internally heated to sublimate the solid raw material, thereby producing a raw material gas containing the above metal. The resulting raw material gas is introduced into a processing container of a film forming apparatus via a pipe extending from the raw material tank. Thereafter, the above film is deposited e.g. on the surface of a semiconductor wafer e.g. by CVD (chemical vapor deposition), whereby the above film can be formed. In the case of a liquid raw material, a raw material gas may be produced e.g. by bubbling the liquid, and the resulting raw material gas may be supplied, together with a carrier gas, to the film forming apparatus.

A raw material gas containing a metal as described above has a relatively low vapor pressure. Accordingly, when producing the raw material gas, the raw material is heated to promote its evaporation. The raw material gas produced can re-solidify when it is cooled while flowing in a pipe e.g. made of stainless steel. In order to prevent the re-solidification, the pipe is generally provided with heaters which may be selected, in the light of shape matching, from various types of heaters such as a block heater, a tape heater, a mantle heater, a silicon rubber heater, etc. The heaters may heat the entire pipe and various parts provided in the pipe.

In place of the above-described Ti and Ta metals, metals having better properties, such as Ru (ruthenium), have recently been proposed. Films of such metals, as typified by a Ru film, have good properties as a barrier layer and, when carrying out Cu plating, can function as a seed film, and thus are very useful.

A raw material gas containing Ru metal is generally produced by heating and sublimating a raw material Ru₃(CO)₁₂, which is solid (powder) at room temperature. The resulting raw material gas containing Ru metal is conveyed by a carrier gas in a pipe to a film forming apparatus and introduced into a processing container. Compared to the above-described Ti raw material gas and Ta raw material gas, the raw material gas containing Ru metal has a considerably lower vapor pressure, and thus is harder to evaporate. Therefore, the pipe and various members as typified by an on-off valve, interposed in the pipe, are sufficiently provided with heaters. By entirely heating the pipe and the members interposed in the pipe by means of the heaters, the raw material gas is prevented from re-solidifying on the way to the film forming apparatus.

The pipe and the on-off valve, however, are usually formed of a material having a relatively low thermal conductivity, such as stainless steel. There is, therefore, a possibility of uneven temperature distribution due to insufficient heat conduction when contact of a heater(s) with the pipe or the various members is insufficient or when the heaters are unevenly arranged. In such a case, a raw material gas will re-solidify or re-liquefy (when the gas is produced e.g. by bubbling of a liquid raw material) especially in low-temperature portions. This may make it impossible to supply a sufficient amount of the raw material gas into the processing container. Furthermore, solid matter will adhere to the inner surface of the pipe, and the adhering solid matter can generate particles.

### DISCLOSURE OF THE INVENTION

The present invention addresses the above problems and has been made to effectively solve the problems. It is therefore an object of the present invention to provide a raw material gas supply system and a film forming apparatus, which can prevent a low-temperature portion from being produced in a raw material gas flow passage, thereby suppressing re-solidification or re-liquefaction of the raw material gas.

Thus, the present invention provides a raw material gas supply system for supplying a raw material gas to a gas use system kept in a reduced pressure atmosphere, said raw material gas supply system comprising: a raw material tank configured to store a liquid raw material or a solid raw material; a raw material conduit connected at one end to the raw material tank and connected at the other end to the gas use system; a carrier gas supply mechanism connected to the raw material tank and configured to supply a carrier gas into the raw material tank while controlling a flow rate of the carrier gas; an on-off valve interposed in the raw material conduit; a heater configured to heat the raw material conduit and the on-off valve; and a temperature control device configured to control the heater, wherein the raw material conduit and the on-off valve are formed of a metal material having good thermal conductivity.

According to the present invention, the raw material conduit, running from the raw material tank to the gas use system, and the on-off valve interposed in the raw material conduit are each formed of a metal material having good thermal conductivity. This can prevent a low-temperature portion from being produced in the raw material gas flow passage, thereby suppressing re-solidification or re-liquefaction of the raw material gas. Therefore, high reproducibility of film forming processing can be maintained and, in addition, the generation of particles can be reduced.

In the raw material gas supply system according to the present invention, the on-off valves may include a plurality of on-off valves, each on-off valve being interposed in the raw material conduit.

In the raw material gas supply system according to the present invention, a flow meter configured to measure a flow rate of the raw material gas may be interposed in the raw material conduit.

In the raw material gas supply system according to the present invention, the on-off valve may include: a valve box in which is formed a gas flow region extending from a gas inlet to a gas outlet across a valve orifice; a valve body capable of seating on a valve seat which defines the valve orifice; a valve shaft coupled to the valve body; an actuator configured to move the valve shaft; and a flexible bellows which, while permitting the movement of the valve shaft, covers the valve shaft to separate the valve shaft from the gas flow region in the valve box, wherein at least the valve box and the valve body are formed of a metal material having good thermal conductivity.

In the raw material gas supply system according to the present invention, the heater may be a rod-like heater or a planar heater (sheet-like heater).

In the raw material gas supply system according to the present invention, the liquid raw material or the solid raw material may be used at a temperature which is lower than the decomposition temperature of the raw material and at a vapor pressure of not more than 133 Pa (1 Torr).

In the raw material gas supply system according to the present invention, the inner diameter of the raw material conduit may be not less than 19.05 mm (¾ inch).

In the raw material gas supply system according to the present invention, the metal material having good thermal conductivity may be at least one metal material selected from the group consisting of aluminum, an aluminum alloy, copper and a copper alloy.

In the raw material gas supply system according to the present invention, the liquid raw material or the solid raw material may be a material selected from the group consisting of Ru₃(CO)₁₂, W(CO)₆, TaCl₅, TAIMATA (registered trademark) and TBTDET (registered trademark).

Further, in the raw material gas supply system according to the present invention, the gas use system may be a main film forming unit configured to form a film on a object to be processed.

The present invention also provides a film forming apparatus for forming a film on an object to be processed, comprising: a processing container capable of evacuation; a holding mechanism configured to hold the object to be processed in the processing container; a heating mechanism configured to heat the object to be processed; a gas introduction member configured to introduce a gas into the processing container; and the raw material gas supply system according to claim 1, connected to the gas introduction member.

The raw material gas supply system and the film forming apparatus according to the present invention can achieve the following advantageous effects: The raw material conduit, running from the raw material tank to the gas use system, and the on-off valve interposed in the raw material conduit are each formed of a metal material having good thermal conductivity. This can prevent a low-temperature portion from being produced in the raw material gas flow passage, thereby suppressing re-solidification or re-liquefaction of the raw material gas. Therefore, high reproducibility of film forming processing can be maintained and, in addition, the generation of particles can be reduced.

### BRIEF DESCRIPTION OF THE DRAWINGS

FIG. 1 is a diagram schematically showing the construction of a film forming apparatus having a raw material gas supply system according to an embodiment of the present invention;

FIG. 2 is a vertical cross-sectional view showing on example of the construction of an on-off valve for use in the raw material gas supply system;

FIG. 3 is a graph showing the relationship between temperature and vapor pressure for major film-forming raw materials;

FIG. 4 is a graph showing the relationship between the inner diameter of a raw material conduit and the amount (calculated value) of a raw material gas supplied in this embodiment; and

FIG. 5 is a diagram illustrating on example of the construction of a raw material tank adapted for bubbling of a liquid raw material.

### MODE FOR CARRYING OUT THE INVENTION

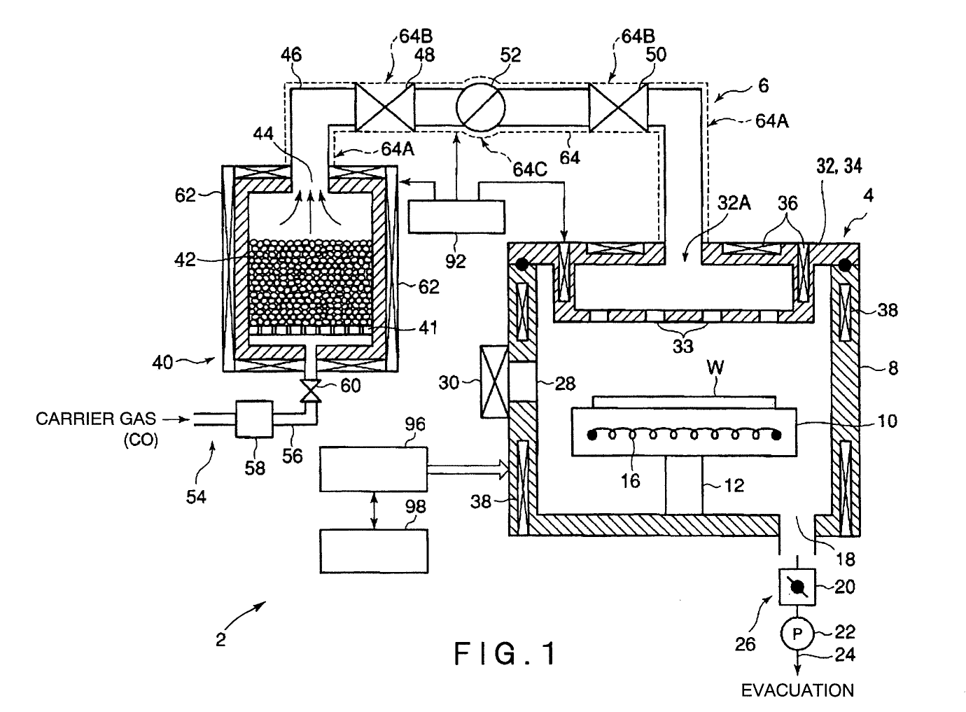

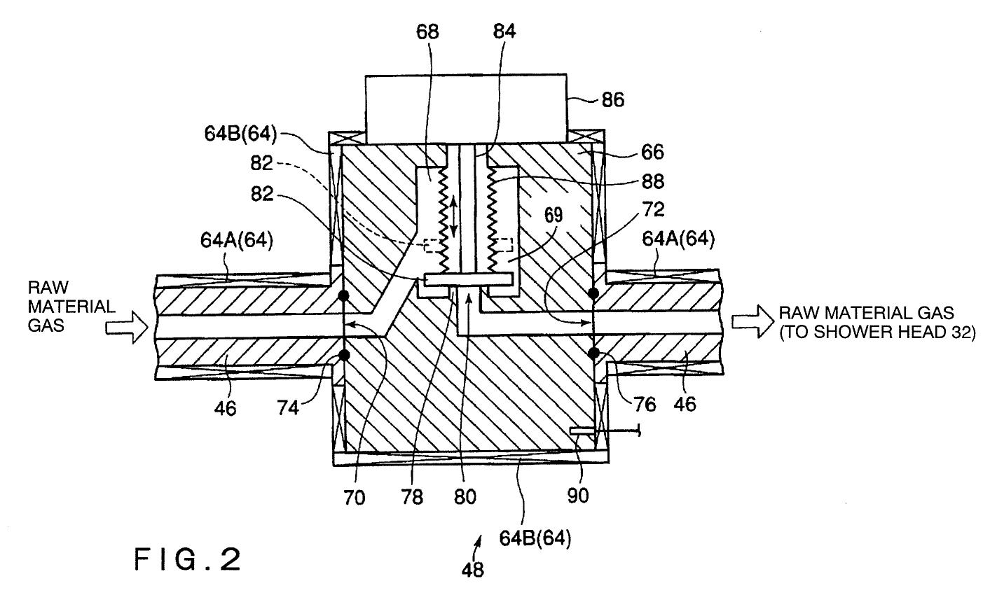

Preferred embodiments of the raw material gas supply system and the film forming apparatus according to the present invention will now be described with reference to the drawings. FIG. 1 is a schematic diagram showing the construction of a film forming apparatus having a raw material gas supply system; and FIG. 2 is a cross-sectional diagram showing the construction of an exemplary on-off valve for use in the raw material gas supply system. The following description illustrates an exemplary case in which a Ru metal film is formed on a semiconductor wafer W as a object to be processed by using Ru₃(CO)₁₂ as a solid material and CO (carbon monoxide) as a carrier gas.

As shown in FIG. 1, the film forming apparatus 2 of this embodiment comprises two main components: a main film forming unit 24 as a gas use system for carrying out film forming processing of a semiconductor wafer W as a object to be processed; and a raw material gas supply system 6 for supplying a raw material gas to the main film forming unit 4.

The main film forming unit 4 will be described first. The main film forming unit 4 includes a cylindrical processing container 8, e.g. made of an aluminum alloy. In the processing container 8 is provided a holding mechanism 10 configured to hold the semiconductor wafer W as a object to be processed. In particular, the holding mechanism 10 includes a disk-shaped stage 14 raised by a support post 12 from the container bottom and on which the wafer W is to be placed. A heating mechanism 16, e.g. comprised of a tungsten wire, is provided in the interior of the stage 14. The heating mechanism 16 is configured to be capable of heating the wafer W held on the stage 14. The heating means 16 is not limited to the tungsten wire: a heating lamp, for example, may be used.

An exhaust port 18 is provided in the bottom of the processing container 8. To the exhaust opening 18 is connected an evacuation system (vacuum evacuation system) 26 having an exhaust conduit 24 in which a pressure regulating valve 20 and a vacuum pump 22 are disoposed in downstream order. The evacuation system 26 is configured to be capable of evacuating the processing container 8 so that the interior of the processing container 8 can be kept in a predetermined reduced pressure atmosphere. An opening 28 for transferring the wafer W is formed in the side wall of the processing container 8. The opening 28 is provided with a gate valve 30 for hermetically opening and closing the opening 28.

A gas introduction member 34, e.g. constructed as a shower head 32, is provided in the ceiling portion of the processing container 8. Gas injection holes 33 are formed in the lower surface of the gas introduction member 34. A necessary gas can be supplied into the processing container 8 via such gas introduction member 34. To the gas inlet 32A of the shower head 32 is connected the raw material gas supply system 6 and a supply system for other necessary gas(es), if any. There is a case in which depending on the gas species used, a raw material gas is mixed with other gas(es) in the shower head 32. There is also a case in which a raw material gas and other gas(es) are separately introduced into the shower head 32, flow separately in the processing container 8, and are mixed in the processing container 8. Instead of the shower head 32, it is possible to use a simple nozzle or the like as the gas introduction member 34.

The shower head 32 and the side wall of the processing container 8 are provided with container-heating heaters 36 and 38, respectively. The shower head 32 and the side wall of the processing container 8 can be kept respectively at a predetermined temperature by the container-heating heaters 36, 38.

The raw material gas supply system 6 will now be described. The raw material gas supply system 6 includes a raw material tank 40 configured to store a solid raw material or a liquid raw material. In this embodiment a solid raw material 42 is stored in the raw material tank 40. As described above, Ru₃(CO)₁₂ is used as the solid raw material 42. The solid raw material 42 has a very low vapor pressure, and thus hardly evaporates. Instead of the solid raw material 42, it is possible to use a liquid raw material from which a raw material gas is produced e.g. by bubbling.

A raw material conduit 46 is provided which is connected at one end to a gas outlet 44 provided in the ceiling portion of the raw material tank 40, and connected at the other end to the gas inlet 32A of the shower head 32 of the main film forming unit 4. A raw material gas generated in the raw material tank 40 is supplied though the raw material conduit 46 to the main film forming unit 4. In the raw material conduit 46 are interposed on-off valves 48, 50 and a flow meter 52 disposed between the on-off valves 48, 50. The flow meter 52 can measure the flow rate of the raw material gas flowing in the raw material conduit 46. The reason for the provision of two on-off valves 48, 50 is to facilitate maintenance work on the raw material gas supply system 6. It is, however, possible to provide only one on-off valve in the raw material conduit 46. Further, it is possible not to provide the flow meter 52 in the raw material conduit 46.

The raw material tank 40 is provided with a carrier gas supply mechanism 54 configured to supply a carrier gas at a controlled flow rate into the raw material tank 40. More specifically, the carrier gas supply mechanism 54 includes a carrier gas pipe 56 for supplying the carrier gas to the raw material tank 40. The carrier gas pipe 56 is connected to the bottom of the raw material tank 40. In the carrier gas pipe 56 are interposed, in downstream order, a flow rate controller 58, such as a mass flow controller, and a carrier gas on-off valve 60. Consequently, a raw material gas can be produced by heating and vaporizing the solid raw material 42 while supplying the carrier gas at a controlled flow rate into the raw material tank 40. A porous plate 41 is installed in the raw material tank 40 at a position near the tank bottom onto which the carrier gas pipe 56 opens. The solid raw material 42 is held on the porous plate 41. The carrier gas supplied from the carrier gas pipe 56 can be uniformly supplied into the raw material tank 40 through holes formed in the porous plate 41.

The raw material tank 40 is provided with a tank-heating mechanism 62 configured to heat the raw material tank 40. The tank-heating mechanism 62 is constructed such that the tank-heating mechanism 62 entirely covers the raw material tank 40 so as to promote vaporization of the solid raw material 42. The heating temperature of the solid raw material 42, to be heated by the tank-heating mechanism 62, is set at a temperature which is lower than the decomposition temperature of the raw material.

The raw material conduit 46, the on-off valves 48, 50 and the flow meter 52 are provided with a heater 64 for heating them. Re-solidification of the raw material gas is prevented by heating the raw material conduit 46, the on-off valves 48, 50 and the flow meter 52 by means of the heater 64. In the embodiment shown in FIG. 1, the raw material conduit 46 is provided with a conduit heater 64A, the on-off valves 48, 50 are provided with a valve heater 64B, and the flow meter 52 is provided with a flow meter heater 64C.

A planar heater (sheet-like heater) such as a tape heater, a mantle heater or a silicon rubber heater, or a rod-like heater such as a cartridge heater can be used as the heater 64 (64A to 64C). Any shape of heater may be used.

A characteristic feature of the present invention is that the raw material conduit 46 and the on-off valves 48, 50 are each formed of a metal material having good thermal conductivity. Preferably, the flow meter is also formed of a metal material having good thermal conductivity. Specifically, aluminum is used in this embodiment as a metal material having good thermal conductivity. Thus, the raw material conduit 46 is entirely formed of aluminum. The inner diameter of the raw material conduit 46 is made not less than 19.05 mm (¾ inch) so as to make the gas flow conductance as large as possible. If the inner diameter of the raw material conduit 46 is smaller than 19.05 mm (¾ inch), the gas flow conductance will be too small. Therefore, there is a fear that the raw material gas, having a low vapor pressure, will not be supplied in a sufficient amount through the raw material conduit 46.

The on-off valves 48, 50 are also formed of aluminum in this embodiment. The schematic construction of the on-off valves 48, 50 will now be described with reference to FIG. 2. The on-off valves 48, 50 have the same construction, and hence the following description will be given of one on-off valve 48.

As shown in FIG. 2, the on-off valve 48 includes a valve box 66 made of aluminum, which is a metal material having good thermal conductivity as described above. An operating space 68 is formed in the valve box 66. A gas inlet 70 and a gas out let 72 are formed in communication with the operating space 68. Thus, a raw material gas flow region (raw material gas flow passage) 69, including the operating space 68 and extending from the gas inlet 70 to the gas outlet 72, is formed in the valve box 66. To the gas inlet 70 is hermetically connected the upstream side of the raw material conduit 46 via a sealing member 74, such as an O-ring. Similarly, to the gas outlet 72 is hermetically connected the downstream side of the raw material conduit 46 via a sealing member 76, such as an O-ring.

A valve orifice 80, defined by a ring-shaped valve seat 78, is formed such that the valve orifice 80 faces the operating space 68. The valve orifice 80 communicates with the gas outlet 72. Thus, the raw material gas flow region (flow passage) 69 extends in the valve box 66 across the valve orifice 80. A generally disk-shaped valve body 82, configured to be seatable on a valve seat 78, is provided in the operating space 68 and over the valve orifice 80. A valve shaft 84 is coupled to the valve body 82. The base of the valve shaft 84 is coupled to an actuator 86. The actuator 86 is configured to be capable of moving the valve body 82 in an opening direction and in a closing direction. Valve orifice 80 opening/closing operations can be performed by the movement of the valve body 82 driven by the actuator 86.

A flexible bellows 88 is provided around the valve shaft 84. The bellows 88 surrounds and covers the valve shaft 84. Such bellows 88 separates the valve shaft 84 from the raw material gas flow region 69 in the valve box 66 while permitting the movement of the valve shaft 84. Thus, the valve shaft 84 is shut off by the bellows 88 from the raw material gas flow region 69.

The valve body 82 is also formed of a metal material having good thermal conductivity (aluminum in this embodiment). Preferably, the bellows 88 and/or the valve shaft 84 is also formed of a metal material having good thermal conductivity (aluminum in this embodiment). It is, of course, possible to form the bellows 88 from stainless steel in the case where a high strength is required of the bellows 88.

As described above, in this embodiment the valve heater 64B, formed in a planar shape, is provided such that the valve heater 64B substantially covers the entire surface of the valve box 66. It is also possible to provide the valve heater 64B such that the valve heater 64B covers only part of the surface of the valve box 66. It is also possible to use a rod-like heater, such as a cartridge heater, as the valve heater 64B instead of the planar heating means. In the case of using such a rod-like valve heater 64B, one or a plurality of rod-like valve heaters 64B may be embedded in appropriate portions of the valve box 66 because the valve box 66 is formed of a metal material having good thermal conductivity.

Similarly, a planar conduit heater 64A may be provided over the entire surface of the raw material conduit 46. It is also possible to provide conduit heaters 64A in the raw material conduit 46 at appropriate intervals in the longitudinal direction of the raw material conduit 46. A rod-like heater(s), such as a cartridge heater(s), may be used as the conduit heater 64A. Also in the case of using such a rod-like conduit heater(s) 64A, the conduit heater(s) 64A may be embedded in the entire raw material conduit 46. Alternatively, rod-like conduit heaters 64A may be embedded at appropriate intervals in the raw material conduit 46.

As shown in FIG. 2, a temperature measuring device 90, e.g. comprised of a thermocouple, is provided in a portion of the valve box 66. The temperature of the valve box 66 can be measure by using the temperature measuring device 90. Though not shown diagrammatically, the raw material tank 40, the raw material conduit 46, the flow meter 52 and the processing container 8 are also each provided with a temperature measuring device in this embodiment. The flow meter 52 may be of the type which includes a bypass pipe and a sensor pipe that bypasses the bypass pipe, and measures the flow rate of a raw material gas based on heat transfer in the raw material gas flowing through the sensor pipe, as disclosed e.g. in JP 2004-109111 A. When such a construction is employed, a metal material having good thermal conductivity, for example aluminum, may be used for the main body of the flow meter 52, the bypass pipe and the sensor pipe.

Referring to FIG. 1, each temperature measuring device 90 is connected to a temperature control device 92. The temperature control device 92 is configured to individually control the heating means, such as the tank-heating mechanism 62, the conduit heater 64A, the valve heater 64B, the flow meter heater 64C, and the container-heating heaters, based on measured values of each temperature measuring device 90.

The overall operations of the film forming apparatus 2, comprising the raw material gas supply system 6 and the main film forming unit 4, such as starting and stopping the supply of a carrier gas, setting a gas flow rate, instructing a set temperature for each heating means, etc., are controlled by commands from an apparatus control device 96 comprised of e.g. a computer. Programs necessary to cause the film forming apparatus 2 to operate are stored in a storage medium 98. The storage medium 98 may be comprised of a memory such as ROM or RAM, a hard disk, a disk-shaped storage medium such as CD-ROM, or any other known storage medium.

The operation of the film forming apparatus 2 thus constructed will now be described. As shown in FIG. 1, the vacuum pump 22 of the evacuation system 26 is continuously driven in the main film forming unit 4 of the film forming apparatus 2. Consequently, the processing container 8 is evacuated, and the pressure in the processing container 8 is kept at a predetermined pressure. A semiconductor wafer W placed on the stage 14 is kept at a predetermined temperature by the heating means 16. Further, the side wall and the shower head 32 of the processing container 8 are each kept at a predetermined temperature by the container-heating heaters 36 and 38, respectively.

The raw material gas supply system 6 has been heated to a predetermined temperature by the tank-heating means 62 and the heater 64 (64A to 64C). After the start of film forming processing, a carrier gas is supplied at a controlled flow rate into the raw material tank 40 via the carrier gas pipe 56 in the raw material gas supply system 6. The solid raw material 42 stored in the raw material tank 40 is heated and vaporized to generate a raw material gas.

The raw material gas generated flows downstream together with the carrier gas in the raw material conduit 46. The raw material gas passes through the upstream on-off valve 48 and flow in the flow meter 52. The flow rate of the raw material gas is monitored by the flow meter 52. The raw material gas then passes through the downstream on-off valve 50, and is introduced via the shower head 32 into the processing container 8 kept in a reduced pressure atmosphere. In the processing container 8, a Ru metal film is formed on the wafer W e.g. by CVD (chemical vapor deposition).

As described above, Ru₃(CO)₁₂, the solid raw material 42, has a very low vapor pressure and hardly evaporates (vaporizes). If there exits even a small low-temperature portion in a raw gas transport path, a raw material gas can re-solidify (or re-liquefy in the case of a liquid raw material) in the low-temperature portion. In conventional raw material gas supply systems, raw material conduits and on-off valves are mostly formed of stainless steel which is inferior in thermal conductivity. If a raw material conduit and an on-off valve are provided with heaters, it is possible that a density difference may be produced in the arrangement of the heaters, and that there may be a portion where a heater cannot be provided. In such cases, an uneven temperature distribution will be produced in the raw material conduit and the on-off valve. It has thus been difficult to set a temperature distribution with high uniformity. Conventional raw material gas supply systems thus have the problem of re-solidification (or re-liquefaction) of a raw material gas in a low-temperature portion of the system.

According to this embodiment, on the other hand, the raw material conduit 46, the on-off valves 48, 50 and, if necessary, the flow meter 52 are each formed of a metal material having good thermal conductivity, for example, aluminum, as described above. This can solve the above-described problem of uneven temperature distribution and achieve a highly uniform temperature distribution. For example, because the valve box 66 and the valve body 82 are each formed of a metal material having good thermal conductivity, even when a rod-like cartridge heater as the valve-heating heater 64B is provided only in part of the valve box 66, heat from the cartridge heater will efficiently diffuse throughout the on-off valves 48, 50. The temperature distribution in the on-off valves 48, 50 can therefore be effectively equalized.

Thus, it becomes possible to prevent re-solidification (or re-liquefaction) of a raw material gas while the raw material gas is flowing in the raw material conduit 46. This makes it possible to maintain high reproducibility of film forming processing and, in addition, prevent the generation of particles. Throughout the raw material tank 40 and the raw material conduit 46, the heating temperature is set within such a temperature range as not to thermally decompose the solid raw material 42, Ru₃(CO)₁₂, and to produce a sufficient amount of raw material gas.

In order to generate the raw material gas having a low vapor pressure in a large amount, it is desirable to make the pressure in the processing container 8 (raw material tank 40) as low as possible, and to make the temperature of the solid raw material 42 as high as possible to the extent that the solid raw material 42 will not be thermally decomposed. In a practical apparatus, for example, the processing pressure in the processing container 8 is set at about 0.1 Torr (13.3 Pa), the temperature of a wafer is set at 200 to 250° C., and the temperature of the shower head 32 and the temperature of the side wall of the processing container 8 are each set at about 75 to 80° C.

Further, the temperatures of the raw material tank 40, the raw material conduit 46, the on-off valves 48, 50 and the flow meter 52 are each evenly set at about 80° C. The decomposition temperature of the raw material Ru₃(CO)₁₂ is around 110° C., though depending on the pressure at the site. As described above, in order to prevent a raw material gas from re-solidifying (or re-liquefying), it is necessary to make the temperature distribution in the system uniform over the entire area of the raw material tank 62 and the raw material conduit 46. A raw material gas will adiabatically expand as the raw material gas flows downstream. The raw material gas is deprived of heat by the adiabatic expansion. In view of this, it is possible to set the temperature of the system such that the temperature increases, in small steps, from the raw material tank 62 toward the downstream side of the raw material conduit 46 (including the on-off valves 48, 50 and the flow meter 52) to the extent that the raw material gas will not be thermally decomposed.

From the view point of enhancing the flow conductance for a raw material gas, the overall length of the raw material conduit 46 is preferably as short as possible. For example, the overall length of the raw material conduit 46 can be made about 1 to 2 m. Measurement was carried out to determine the temperature distribution in the raw material gas supply system 6 of this embodiment and the temperature distribution in a conventional raw material gas supply system having a raw material conduit made of stainless steel. As a result, the temperature difference in the temperature distribution along the length of the respective raw material conduit, including on-off valves, was about 7° C. in the conventional system, whereas the temperature difference was as small as about 1° C. in the system of this embodiment. As will be appreciated from the results, the temperature distribution along the length of the raw material conduit 46 can be significantly equalized according to this embodiment.

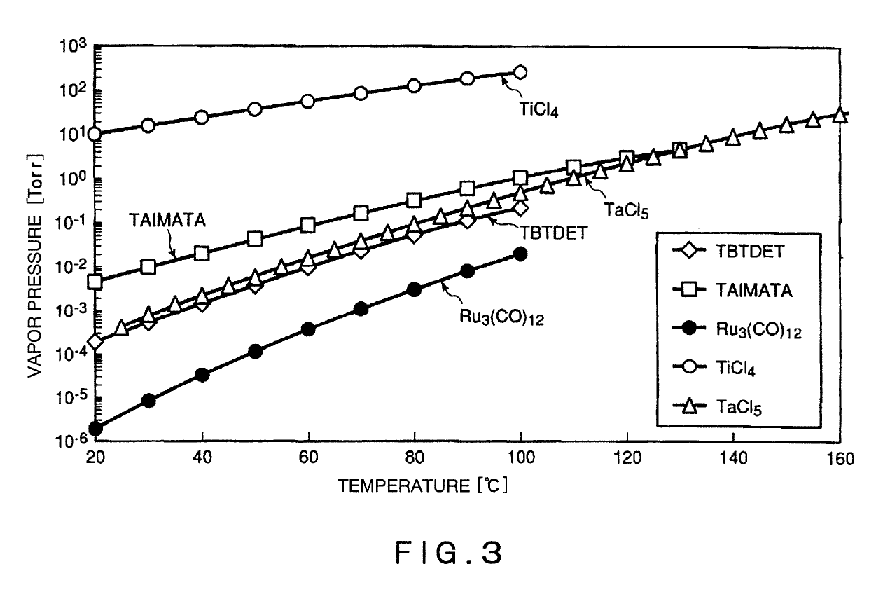

The relationship between temperature and vapor pressure was determined for major film forming raw materials, the results of which are shown in FIG. 3. In the graph of FIG. 3, the abscissa represents temperature and the ordinate represents vapor pressure. In FIG. 3 are shown data on TBTDET (registered trademark), TAIMATA (registered trademark), Ru₃(CO)₁₂, TiCl₄ and TaCl₅. Of these raw materials, TBTDET and TiCl₄ are liquid raw materials which are liquid at room temperature, while TAIMATA, Ru₃(CO)₁₂ and TaCl₅ are solid raw materials.

TBTDET and TAIMATA contain Ta as a metal element. Each raw material was heated to a temperature which is lower than the decomposition temperature. As can be seen from the graph of FIG. 3, the vapor pressure of each raw material increases moderately as the temperature rises from 20° C.; and Ru₃(CO)₁₂ has a much lower vapor pressure than the other raw materials. Thus it can be said that Ru₃(CO)₁₂ is harder to vaporize. For example, at a heating temperature of 100° C., the vapor pressure of Ru₃(CO)₁₂ is about 1/10000 of the vapor pressure of TiCl₄, and about 1/10 of the vapor pressure of TBTDET.

In general, TiCl₄ is said to be a low-vapor pressure material, whose vapor pressure is about 1 Torr at room temperature. However, the vapor pressure of TiCl₄ is considerably higher than the vapor pressures of the other raw materials shown in FIG. 3. Further, a sufficient amount of TiCl₄ gas can be obtained practically by vaporizing TiCl₄, supplied in a liquid form, by means of a vaporizer. On the other hand, the raw material gas supply system 6 of this embodiment is very effective especially when a material having a very low vapor pressure, such as Ru₃(CO)₁₂, is used as a raw material. The raw material gas supply system 6 can also be advantageously used when using, as a raw material, any one of the other raw materials shown in FIG. 3, i.e. TBTDET, TAIMATA and TaCl₅, or W(CO)₆ not shown in the graph.

In this embodiment a raw material is heated in a use temperature range lower than the decomposition temperature, and is preferably used at a vapor pressure of not more than 133 Pa (1 Torr), more preferably not more than 13.3 Pa (0.1 Torr), for the following reasons: In this embodiment the flow rate of a raw material gas is controlled though control of the flow rate of a carrier gas and control of the temperature of the raw material tank 40, without using a flow rate controller such as a mass flow controller. In the case of such a manner of controlling the flow fate of a raw material gas, there is a possibility that the flow rate control will be practically difficult in a condition that the vapor pressure is high, i.e. the raw material gas is generated in a large amount. It is preferred that the lower limit of vapor pressure be about 133×10⁻³ Pa (1×10⁻⁵ Torr). When the vapor pressure is lower than the value, a sufficient film thickness will not be obtained within a reasonable time.

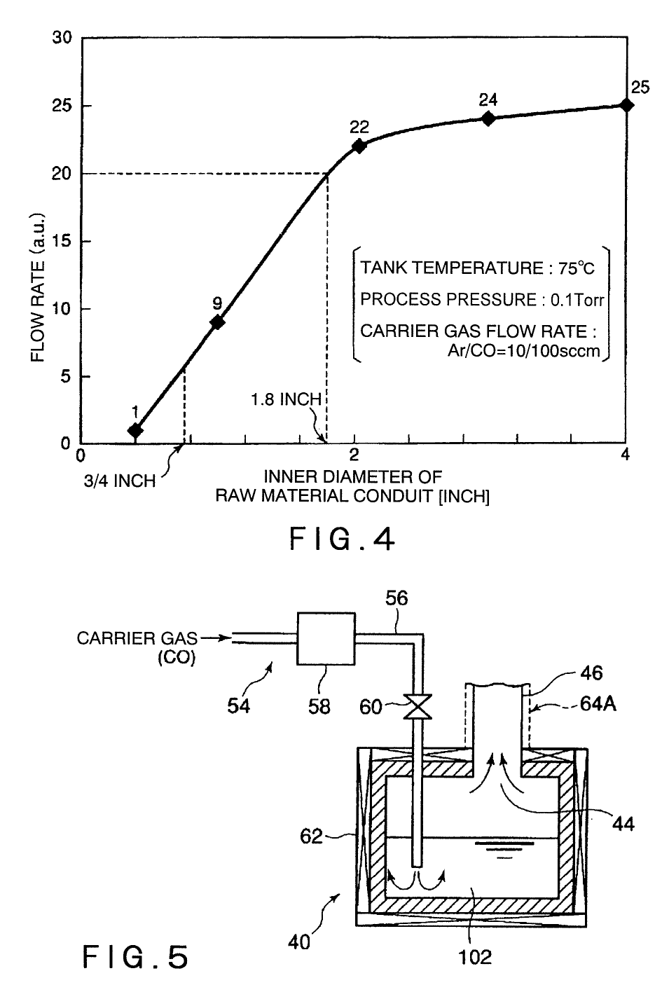

Measurement was conducted to determine the relationship between the inner diameter of the raw material conduit 46 and the amount (calculated value) of a raw material gas supplied in this embodiment. The results are shown in FIG. 4. In the graph of FIG. 4, the abscissa represents the inner diameter (inch) of the raw material conduit and the ordinate represents the flow rate (a.u.). 1 inch is equal to 2.54 cm. The process conditions upon the measurement were as follows: the temperature of the raw material tank 40 was 75° C.; the pressure in the processing container 8 was 0.1 Torr; and the flow rate of carrier gas (Ar/CO) was 10/100 sccm. A mixture of Ar gas and CO gas was used as a carrier gas upon the measurement.

As shown in FIG. 4, as the inner diameter of the raw material conduit 46 increases from about 0.5 inch, the conductance increases, and therefore the gas flow rate also increases gradually. The increase in the flow rate rapidly drops at an inner diameter slightly smaller than 2 inches, and the flow rate comes into saturation. According to empirical rule, in the case where a raw material gas having a very low vapor pressure, as typified by Ru₃(CO)₁₂, is to be supplied, the lower limit of the inner diameter of the raw material conduit 46 is about ¾ inch. In order to obtain a raw material gas in an amount at least 0.8 times the saturation amount, the inner diameter of the raw material conduit 46 is preferably made not less than 1.8 inches. The upper limit of the inner diameter of the raw material conduit 46 is 4 inches. A further increase in the flow rate cannot be expected if the inner diameter is made larger.

While the present invention has been described with reference to the case in which a raw material gas is produced from the solid raw material 42, it is also possible to use a liquid raw material and produce a raw material gas e.g. by bubbling of the liquid material, and to convey the resulting raw material gas with a carrier gas. The construction of a raw material tank for carrying out such bubbling will now be described with reference to FIG. 5. FIG. 5 is a diagram illustrating the construction of an exemplary raw material tank adapted for bubbling of a liquid raw material. In FIG. 5, the same reference numerals are used for the similar components as those shown in FIG. 1, and a description thereof will be omitted.

A liquid raw material 102 is stored in a raw material tank 40. The above-described carrier gas pipe 56 penetrates the ceiling portion of the raw material tank 40 and extends into the raw material tank 40. The carrier gas pipe 56 is disposed such that the front end is immersed in the liquid raw material 102 stored in the raw material tank 40. A carrier gas is supplied at a controlled flow rate through the carrier gas pipe 56 into the liquid raw material 102. A raw material gas is produced by carrying out bubbling of the liquid raw material 102 with the carrier gas.

Though in the above-described embodiment Ru₃(CO)₁₂ is used as a raw material, it is also possible to use, for example, a raw material selected from the group consisting of Ru₃(CO)₁₂, W(CO)₆, TaCl₅, TAIMATA (registered trademark) and TBTDET (registered trademark).

Though in the above-described embodiment aluminum is used as a metal material having good thermal conductivity, it is also possible to use, for example, at least one metal material selected from the group consisting of aluminum, an aluminum alloy, copper and a copper alloy as a metal material having good thermal conductivity. Instead of the use of CO gas as a carrier gas in the above-described embodiment, it is also possible to use as a carrier gas a rare gas, such as Ar or He, or an inert gas, such as N_{Z}.

While the present invention has been described with reference to the case in which film deposition processing of an object to be processed by thermal CVD is carried out by means of the main film forming unit 4, the present invention is not limited to such application: the present invention can also be applied to e.g. an apparatus configured to carry out film forming processing of an object to be processed by using a plasma. Further, though a semiconductor wafer is used as an object to be processed in the above-described embodiment, the present invention is also applicable to the use of a glass substrate, an LCD substrate, a ceramic substrate, etc.

1. A raw material gas supply system for supplying a raw material gas to a gas use system kept in a reduced pressure atmosphere, the raw material gas supply system comprising:
a raw material tank configured to store a liquid raw material or a solid raw material;
a raw material conduit connected at one end to the raw material tank and connected at the other end to the gas use system;
a carrier gas supply mechanism connected to the raw material tank and configured to supply a carrier gas into the raw material tank while controlling a flow rate of the carrier gas;
an on-off valve interposed in the raw material conduit;
a heater configured to heat the raw material conduit and the on-off valve; and
a temperature control device configured to control the heater,
wherein the raw material conduit and the on-off valve are formed of a metal material having good thermal conductivity.

2. The raw material gas supply system according to claim 1,
wherein the on-off valve includes a plurality of on-off valves, each being interposed in the raw material conduit.

3. The raw material gas supply system according to claim 1,
wherein a flow meter configured to measure a flow rate of the raw material gas is interposed in the raw material conduit.

4. The raw material gas supply system according to claim 1,
wherein the on-off valve includes:
a valve box in which is formed a gas flow region extending from a gas inlet to a gas outlet across a valve orifice;
a valve body capable of seating on a valve seat which defines the valve orifice;
a valve shaft coupled to the valve body;
an actuator configured to move the valve shaft; and
a flexible bellows which, while permitting the movement of the valve shaft, covers the valve shaft to separate the valve shaft from the gas flow region in the valve box,
wherein at least the valve box and the valve body are formed of a metal material having good thermal conductivity.

5. The raw material gas supply system according to claim 1,
wherein the heater is a rod-like heater or a planar heater.

6. The raw material gas supply system according to claim 1,
wherein the liquid raw material or the solid raw material is used at a temperature which is lower than the decomposition temperature of the raw material and at a vapor pressure of not more than 133 Pa.

7. The raw material gas supply system according to claim 1,
wherein the inner diameter of the raw material conduit is not less than 19.05 mm.

8. The raw material gas supply system according to claim 1,
wherein the metal material having good thermal conductivity is at least one metal material selected from the group consisting of aluminum, an aluminum alloy, copper and a copper alloy.

9. The raw material gas supply system according to claim 1,
wherein the liquid raw material or the solid raw material is a material selected from the group consisting of Ru₃(CO)₁₂, W(CO)₆, TaCl₅, TAIMATA (registered trademark) and TBTDET (registered trademark).

10. The raw material gas supply system according to claim 1,
wherein the gas use system is a main film forming unit configured to form a film on a object to be processed.

11. A film forming apparatus for forming a film on an object to be processed, comprising:
a processing container capable of evacuation;
a holding mechanism configured to hold the object to be processed in the processing container;
a heating mechanism configured to heat the object to be processed;
a gas introduction member configured to introduce a gas into the processing container; and
the raw material gas supply system according to claim 1, connected to the gas introduction member.
